(19) United States
(12) Patent Application Publication
(10) Pub. No.: US 2026/0130175 A1
(43) Pub. Date: May 7, 2026

(54) MASS TRANSFER METHOD

(71) Applicant: Century Technology (Shenzhen) Corporation Limited, Shenzhen (CN)

(72) Inventors: Chen-Fu Mai, New Taipei (TW); Ping Liu, Shenzhen (CN); Jie Xiao, Shenzhen (CN); Ze-Yuan Li, Shenzhen (CN); Meng-Chieh Tai, New Taipei (TW)

(21) Appl. No.: 19/436,062

(22) Filed: Dec. 30, 2025

Related U.S. Application Data
(62) Division of application No. 17/721,547, filed on Apr. 15, 2022, now Pat. No. 12,538,750.

(30) Foreign Application Priority Data
Dec. 23, 2021 (CN) 202111590271.3

(51) Int. Cl. H10P 72/70; H10H 20/01; H10H 20/857; H10W 90/00

(52) U.S. Cl. CPC H10P 72/74; H10H 20/857; H10W 90/00; H10H 20/0364; H10P 72/7408; H10P 72/7432

(57) ABSTRACT

A mass transfer method includes providing at least one transfer cavity including a bottom plate with through holes and a cavity wall connecting the bottom plate; providing an array substrate with capture holes; placing micro light emitting diodes into each transfer cavity; attaching the array substrate to the bottom plate; aligning each through hole with a corresponding capture hole by moving the array substrate; causing the micro light emitting diodes to fall into a corresponding capture hole through the corresponding one through hole; and continuously moving the array substrate such that each capture hole in the array substrate is filled with one micro light emitting diode.

### FIELD

The subject matter herein generally relates to display field, particularly relates to a mass transfer method.

### BACKGROUND

Recently, most displays are liquid crystal displays. With the development of display technology, the requirements for display resolution and contrast are becoming higher. Micro light emitting diode (micro-LED) display technology, a new technology with higher brightness, better luminous efficiency, and lower efficiency, is being developed. Since micro-LED are sized in tens of microns or even less, assembling such small components on a display substrate with high efficiency and low cost is problematic.

Therefore, there is room for improvement in the art.

### BRIEF DESCRIPTION OF THE DRAWINGS

Implementations of the present technology will now be described, by way of embodiments only, with reference to the attached figures.

FIG. 1 is a view of a mass transfer device according to an embodiment of the present disclosure.

FIG. 2 is an exploded view of a transfer cavity according to an embodiment of the present disclosure.

FIG. 3 is a view of a mass transfer system according to embodiment of the present disclosure.

FIG. 4 is a planar view of an array substrate in a display according to an embodiment of the present disclosure.

FIG. 5 is a cross-sectional view of the mass transfer system according to an embodiment of the present disclosure.

FIG. 6 is a cross-sectional view of a mass transfer system according to another embodiment of the present disclosure.

FIG. 7 is a view showing a state of the array substrate in the display in the mass transfer process shown in FIG. 6.

FIG. 8 is a flowchart of a mass transfer method according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as coupled, whether directly or indirectly through intervening components, and is not necessarily limited to physical connections. The connection can be such that the objects are permanently coupled or releasably coupled. The term “comprising” when utilized, means “including, but not necessarily limited to”; it specifically indicates open-ended inclusion or membership in the so-described combination, group, series, and the like.

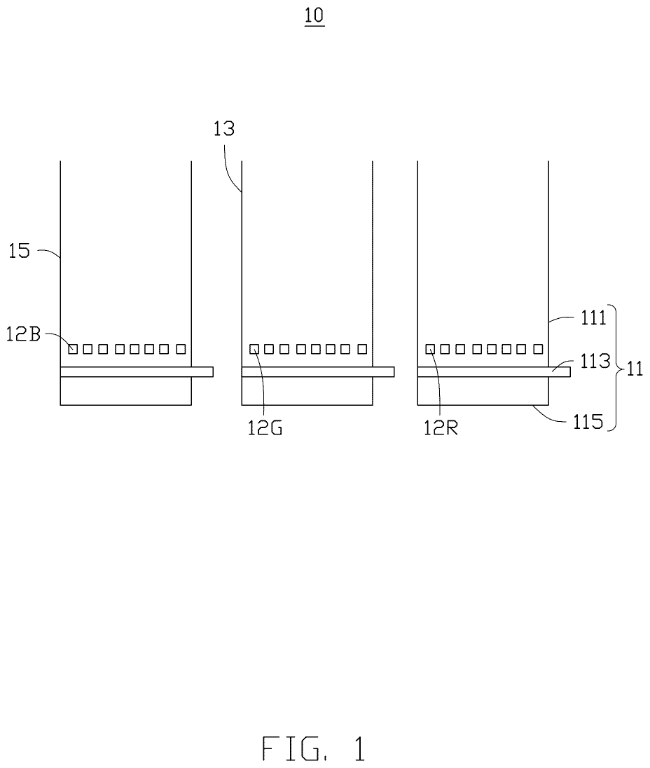

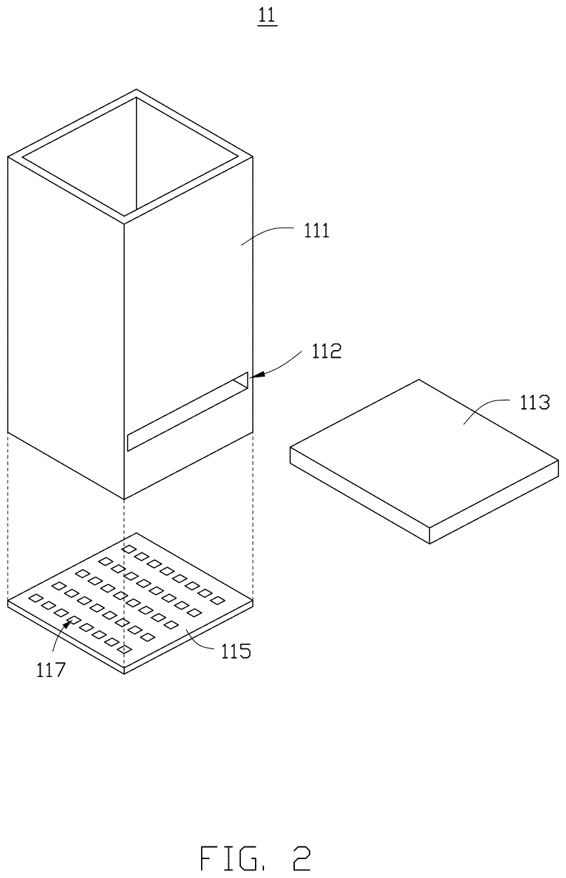

FIG. 1 illustrates a mass transfer device 10. The mass transfer device 10 includes at least one transfer cavity 11. FIG. 1 shows three transfer cavities 11 as an example. Each transfer cavity 11 is used to receive a plurality of micro light emitting diodes (micro-LEDs) 12R. The transfer cavity 11 includes a bottom plate 115 and a cavity wall 111 connecting the bottom plate 115. As shown in FIG. 2, the bottom plate 115 defines a plurality of through holes 117 arranged in an array. The transfer cavity 11 is configured to transfer the plurality of micro-LEDs 12R to an array substrate of a display panel, by the through holes 117.

In one embodiment, the mass transfer device 10 also includes a baffle 113. An opening 112 is defined in the cavity wall 111, and the baffle 113 is detachably arranged in the transfer cavity 11 through the opening 112. The baffle 113 is used to carry the micro-LEDs 12R and to control the micro-LEDs 12R to fall onto the bottom plate 115, thereby the micro-LEDs 12R are controlled to pass through the through holes 117. Specifically, the baffle 113 can be moved inside and outside of the transfer cavity 11 through the opening 112. When the baffle 113 is inside of the transfer cavity 11, the micro-LEDs 12R are located on a side of the baffle 113 away from the bottom plate 115 and are supported by the baffle 113. The baffle 113 covers the bottom plate 115. That is, the baffle 113 covers and blocks each through hole 117, so as to prevent the plurality of micro LEDs 12R falling through the plurality of through holes 117. After the baffle 113 is moved from inside to outside of the transfer cavity 11, the through holes 117 are not covered by the baffle 113, so the micro-LEDs 12R drop from the inside to the outside of the transfer cavity 11 by any through hole 117.

In the present embodiment, the mass transfer device 10 includes three transfer cavities, transfer cavity 11, transfer cavity 13, and transfer cavity 15. The structures of the three transfer cavities are the same. Micro-LEDs in the same transfer cavity emit light of one certain color, and micro-LEDs in different transfer cavities emit light of different colors. Specifically, the transfer cavity 11 is used to receive a plurality of micro-LEDs 12R emitting first color light (such as red light), the transfer cavity 13 is used to receive a plurality of micro-LEDs 12G emitting second color light (such as green light), and the transfer cavity 15 is used to receive a plurality of micro-LEDs 12B emitting third color light (such as blue light). A size of each micro-LED 12R, a size of each micro-LED 12G, and a size of each micro-LED 12B are the same. In other embodiments, a size of each micro-LED 12R, a size of each micro-LED 12G, and a size of each micro-LED 12B are different. At this time, the sizes of the through holes for different transfer cavities are different, so that the micro-LEDs having different sizes can drop from inside to the outside of the transfer cavity through the through holes of corresponding transfer cavity.

In one embodiment, the baffle 113 may be arranged in the opening 112 simply to block the opening 12 without covering the bottom plate 115, to avoid the micro-LED 12R from falling out of the transfer cavity 11 by the opening 112.

In one embodiment, the through holes 117 in the bottom plate 115 have certain rules of arrangement. For the transfer cavity 11 to transfer a plurality of micro-LEDs 12R to the array substrate of the display panel, the through holes 117 are arranged to correspond to and be aligned with a plurality of capture holes in the array substrate one by one, so as to realize the mass transfer of a plurality of micro-LEDs 12R to the array substrate. That is, the transfer cavity 11 can set a distance between adjacent two through holes 117 on the bottom plate 115 according to a distance between adjacent two capture holes on the array substrate.

The mass transfer device 10 provided by the present disclosure accommodates a plurality of micro-LEDs 12R by setting at least one transfer cavity 11, and a plurality of through holes 117 are defined in the bottom plate 115, which can make the micro-LEDs 12R drop from the inside to the outside of the transfer cavity 11 by the through holes 117, so as to realize the mass transferring of micro-LEDs 12R. By setting at least three transfer cavities 13, each of which accommodating one color of micro-LEDs 12, the micro-LEDs 12R, the micro-LEDs 12G, and the micro-LEDs 12B can be transferred in large quantities onto the array substrate.

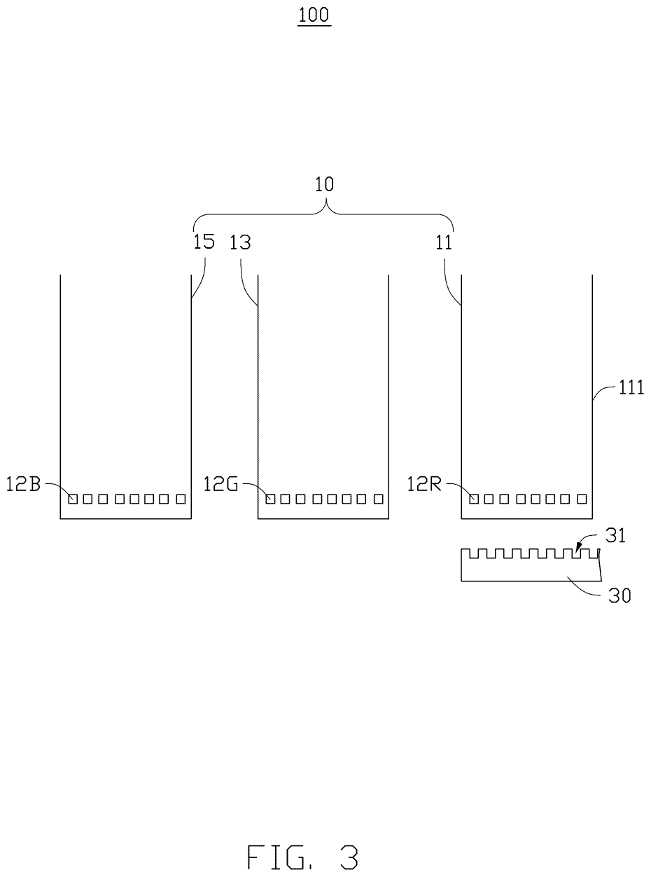

FIG. 3 illustrates a mass transfer system 100. The mass transfer system 100 includes the above mass transfer device 10 and an array substrate 30 for installing micro-LEDs. The array substrate 30 defines a plurality of capture holes 31 arranged in an array, and the array substrate 30 is movably arranged on a side of the bottom plate 115 away from the cavity wall 111.

In one embodiment, each through hole 117 in the transfer cavity 11 can be aligned with one capture hole 31, so that the micro-LEDs 12R in the transfer cavity 11 can fall into the capture holes 31 one-to-one through the through holes 117 at the same time. Specifically, each through hole 117 is aligned with one capture hole 31, and one micro-LED 12R can fall into one capture hole 31 by one through hole 117. Each capture hole 31 is used to receive one micro-LED 12R.

In one embodiment, unfilled capture holes 31 in the array substrate 30 can each be aligned with one through hole 117 by moving the array substrate 30, so that the micro-LEDs 12R continues to fall into the unfilled capture hole 31 through the through holes 117. Specifically, in the present embodiment, a number of the micro-LEDs 12R contained in the transfer cavity 11 is greater than a number of the capture holes 31 in the array substrate, and a number of capture holes 31 in the array substrate is greater than a number of the through holes 117 of the transfer cavity 11. When each through hole 117 is aligned with one capture hole 31, the capture hole 31 aligned with the through hole 117 is filled by the micro-LED 12R dropping thereinto. At this time, the array substrate 30 also includes some capture holes 31 not filled by the micro-LED 12R. By moving the array substrate 30, the unfilled capture hole 31 can be aligned with the through hole 117, so that the micro-LED 12R falls into the unfilled capture hole 31 by the through hole 117. In other embodiments, a number of capture holes 31 of the array substrate can also be equal to a number of the through holes 117 of the transfer cavity 11, so that when each through hole 117 is aligned with the capture hole 31, each capture holes 31 can be filled by one micro-LED 12R.

In one embodiment, the array substrate 30 may be attached to the bottom plate 115 and be moved so that the micro-LEDs 12R fall out of the transfer cavity 11 only when each through hole 117 is aligned with one unfilled capture hole 31. Specifically, when the array substrate 30 is attached to the bottom plate 115 and is moved, the array substrate 30 can also be used to control the micro-LED 12R to fall out of the transfer cavity 11. Until a through hole 117 is aligned with one capture hole 31, the micro-LED 12R is not able to fall out through the through hole 117 because the array substrate 30 is attached to the bottom plate 115. When the through hole 117 is aligned with one capture hole 31, one and only one micro-LED 12R falls into the unfilled capture hole 31 through the through hole 117. If the capture hole 31 has already received one micro-LED 12R, the received micro-LED 12R in the capture hole 31 prevents another micro-LED 12R from falling into the capture hole 31, so that only one micro-LED 12R is filled in each capture hole 31.

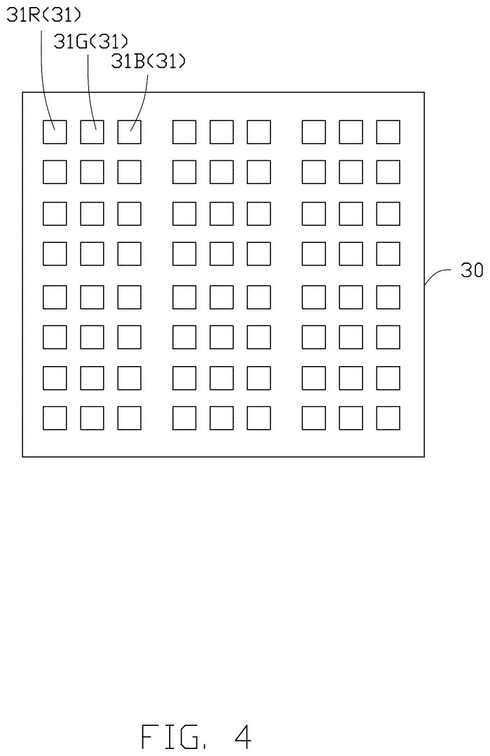

In one embodiment, as shown in FIG. 3 and FIG. 4, the capture holes 31 in the array substrate 30 may include a plurality of capture holes 31R, a plurality of capture holes 31G, and a plurality of capture holes 31B. Each capture hole 31R is used to receive one micro-LED 12R from the transfer cavity 11, each capture hole 31G is used to receive one micro-LED 12G from the transfer cavity 13, and each capture hole 31B is used to receive one micro-LED 12B from the transfer cavity 15. Specifically, the transfer cavity 11, the transfer cavity 13, and the transfer cavity 15 may be arranged in a row or in a column. The array substrate 30 can move from the transfer cavity 11, to the transfer cavity 13, and to the transfer cavity 15 in turn, so that each capture hole 31 is filled with one micro-LED from each of the three transfer cavities.

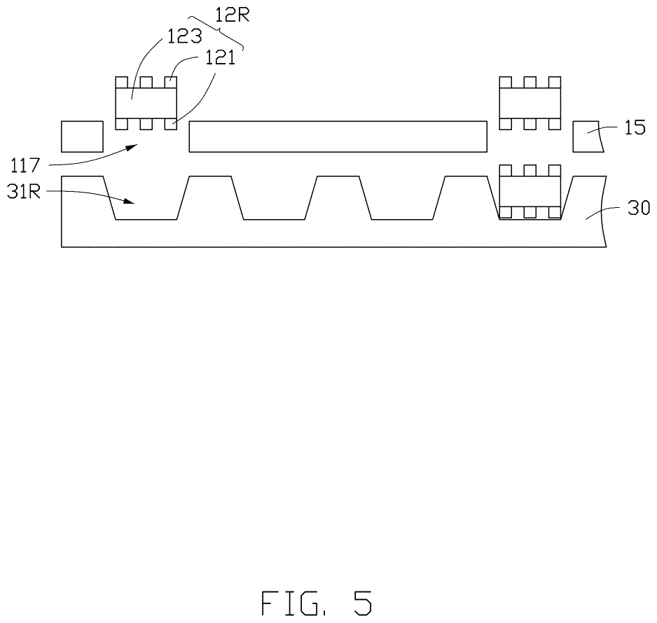

In one embodiment, as shown in FIG. 5, the micro-LED 12R falls into the capture hole 31R through the through hole 117 by gravity. The micro-LED 12R includes a light-emitting part 123 and two electrodes 121 arranged on opposite sides of the light-emitting part 123, so that when each micro-LED 12R falls by gravity, one of the electrodes 121 makes contact with the bottom of the capture hole 31R.

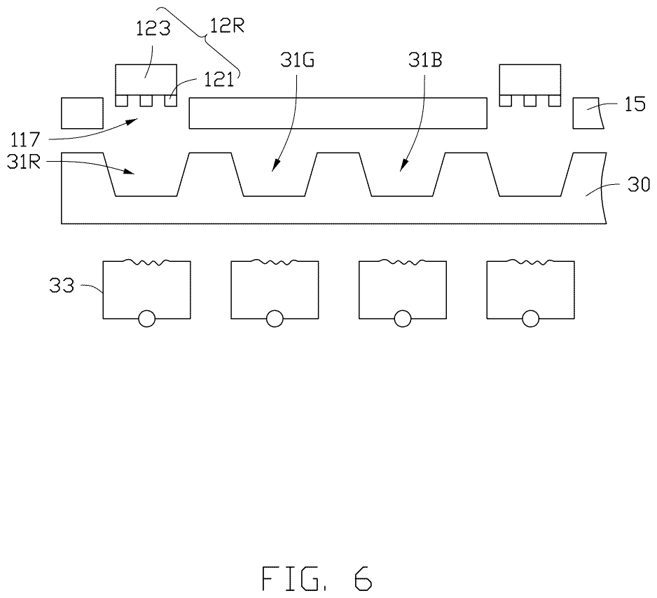

In one embodiment, as shown in FIG. 6, each micro-LED 12R has a first magnetic pole, and the mass transfer system 100 also includes a magnetic generator 33. The magnetic generator 33 is arranged on a side of the array substrate 30 away from the bottom plate 115 to generate a magnetic field to attract the first magnetic pole of each micro-LED 12R, so that the first magnetic pole of each micro-LED 12R receives an adsorption force due to the magnetic field, so that when each micro-LED 12R is transferred from the through hole 117 to the capture hole 31R, the side of each micro-LED 12R with the first magnetic pole is always down, that is to say, facing the array substrate 30. Specifically, three magnetic generators 33 can be set to correspond to the capture holes 31R, the capture holes 31G, and the capture holes 31B respectively, and a corresponding one magnetic generator 33 is powered on when the array substrate 30 is transferred to different transfer cavities, so as to prevent the micro-LED from sticking to the side of the bottom plate 115 away from the array substrate 30 and affecting undropped micro-LEDs from falling out from the through hole 117.

In one embodiment, the micro-LED 12R includes a light emitting part 123 and an electrode 121, and the electrode 121 is the first magnetic pole. Under the action of the magnetic generator 33, the electrode 121 of the micro-LED 12R approaching the array substrate 30 is pointed towards the magnetic generator 33, so as to fall into the capture hole 31R through the through hole 117.

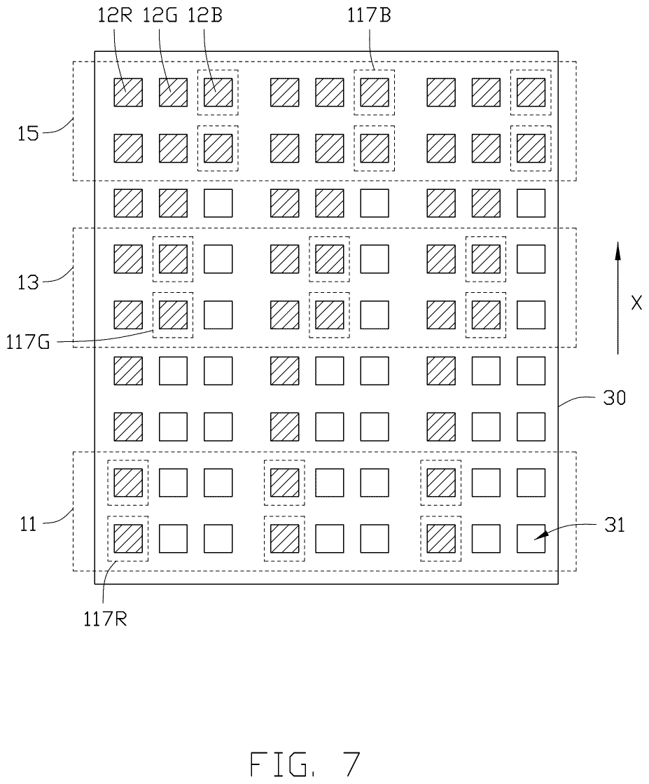

In one embodiment, as shown in FIG. 7, the micro-LEDs in the transfer cavity 11, the transfer cavity 13, and the transfer cavity 15 fill a plurality of capture holes 31 in the array substrate 30. That is, the array substrate 30 moves along a first direction X, so that the through holes 117R of the transfer cavity 11, the through holes 117G of the transfer cavity 13, and the through holes 117B of the transfer cavity 15 are in turn aligned with the capture holes 31 of the array substrate 30, so that a plurality of micro-LEDs 12R, 12G, and 12B are arranged on the array substrate 30. The micro-LED 12R emits red light, the micro-LED 12G emits green light, and the micro-LED 12B emits blue light. The mass transfer system 100 prepares a display panel by transferring red, green, and blue micro-LEDs onto the array substrate 30. In other embodiments, after the micro-LEDs 12R are transferred to all capture holes 31R of the array substrate 30, the micro-LEDs 12G and the micro-LEDs 12B can be transferred respectively to capture holes 31G and capture holes 31B of the array substrate 30 in turn.

In this embodiment, each micro-LED is used as a light-emitting element of the display panel and corresponds to a sub-pixel of the display panel. That is, the display panel defines a plurality of sub-pixels arranged in an array, a corresponding one micro-LED is in each sub-pixel.

The mass transfer system 100 in the present disclosure can transfer a plurality of micro-LEDs into a plurality of capture holes 31 in the array substrate 30 in batches by setting the mass transfer device 10 and the movable array substrate 30. By setting the moving direction of the array substrate 30 and/or the arrangement direction of the transfer cavities 11, 13, and 15, all capture holes 31 can be filled with micro-LEDs of appropriate colors, so as to realize the image display function.

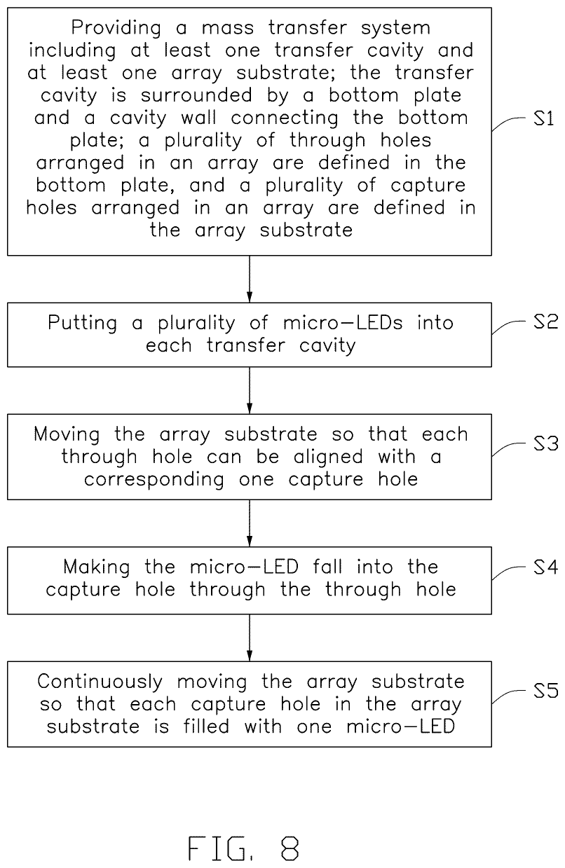

The present disclosure also provides a mass transfer method. As shown in FIG. 8, the mass transfer method includes the following step S1 to step S5.
Step S1: providing a mass transfer system including at least one transfer cavity and at least one array substrate. The transfer cavity includes a bottom plate and a cavity wall connecting the bottom plate. A plurality of through holes in an array is defined in the bottom plate, and a plurality of capture holes in an array are defined in the array substrate.
Step S2: placing a plurality of micro-LEDs into each transfer cavity.
Step S3: moving the array substrate so that each through hole can be aligned with a corresponding one capture hole.
Step S4: making the micro-LED to fall into the capture hole through the through hole.
Step S5: continuously moving the array substrate so that each capture hole in the array substrate is filled with one micro-LED.

In one embodiment, the mass transfer system in step S1 is the mass transfer system 100 in the embodiment of the present disclosure, which includes a transfer cavity 11, a transfer cavity 13 and a transfer cavity 15 having the same structure. Taking the transfer cavity 11 as an example, it also includes a baffle 113, which can be moved inside and outside of the transfer cavity 11 by the opening 112 in the cavity wall 111.

In one embodiment, before the step S2, it also includes moving the baffle 113 so that the bottom plate 115 is completely covered by the baffle 113. That is, each through hole 117 is covered by the baffle 113. After step S2, it also includes removing the baffle 113 so that each through hole 117 can pass through the micro-LED 12R. That is, the baffle 113 is used to control whether the micro-LED 12R can pass through the through hole 117. When filling the micro-LEDs 12R into the transfer cavity 11, the baffle 113 prevents the micro-LEDs 12R from passing through the through hole 117. After placing the micro-LEDs 12R into the transfer cavity, the baffle 113 is remove from the transfer cavity, so that the micro-LEDs 12R can fall out of the transfer cavity 11 in batches through the through holes 117. The baffle 113 may also be used to cover the opening 112 to prevent the micro-LEDs 12R from falling out of the transfer cavity 11 from the opening 112.

In one embodiment, step S2 specifically includes putting micro-LEDs emitting light of a same color into the same transfer cavity, and different transfer cavities are placed micro-LEDs emitting light of different colors. That is, the micro-LEDs 12R emitting red light are placed in the transfer cavity 11, the micro-LEDs 12G emitting green light are placed in the transfer cavity 13, and the micro-LEDs 12B for emitting blue light are placed in the transfer cavity 15.

In one embodiment, step S4 specifically includes making each micro-LED to fall into the capture hole 31 by gravity. At this time, the micro LED includes a light-emitting part 123 and electrodes 121 arranged on opposite sides of the light-emitting part 123, so that when the micro-LED falls into the capture hole 31 under the action of gravity, one electrode 121 always contacts the bottom of the capture hole 31.

In one embodiment, step S4 specifically includes providing a magnetic generator 33 on a side of the array substrate 30 away from the bottom plate 115 to generate a magnetic field. At this time, each micro-LED has a first magnetic pole, and the micro-LEDs with the first magnetic poles fall into the capture hole 31 through the through holes 117 under the action of the magnetic field. Specifically, under the action of the magnetic field, the first magnetic pole receives an adsorption force, so that when each micro-LED is transferred from the through hole 117 into the capture hole 31, the side of each micro-LED with the first magnetic pole always faces the array substrate 30.

In one embodiment, step S5 specifically includes: attaching the array substrate 30 to three transfer cavities in turn or at the same time, so that a plurality of capture holes 31 on the array substrate 30 are respectively filled with micro light-emitting diodes used to emit light of different colors in the three transfer cavities.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A mass transfer method comprising:
Block S1-1: providing at least one transfer cavity, wherein each of the at least one transfer cavity comprises a bottom plate, a cavity wall connecting to the bottom plate, and a plurality of through holes defined in the bottom plate;
Block S1-2: providing an array substrate defining a plurality of capture holes;
Block S2-1: placing a plurality of micro light emitting diodes into each of the at least one transfer cavity;
Block S2-2: attaching the array substrate to the bottom plate;
Block S3: aligning corresponding capture holes of the plurality of capture holes with the plurality of through holes by moving the array substrate;
Block S4: causing the plurality of micro light emitting diodes to fall into the corresponding capture holes through the plurality of through holes; and
Block S5: repeating Block S3 and Block S4 until each of the plurality of capture holes in the array substrate is filled with one of the plurality of micro light emitting diodes.

2. The mass transfer method of claim 1, wherein in Block S1-1, each of the at least one transfer cavity further comprises an opening defined in the cavity wall and a baffle detachably arranged in each of the at least one transfer cavity through the opening;
before Block S2-1, the mass transfer method further comprises:
Block S1-3: moving the baffle such that the bottom plate is covered by the baffle;
after Block S2-1, the mass transfer method further comprises:
Block S2-3: removing the baffle from the transfer cavity.

3. The mass transfer method of claim 2, wherein Block S1-3 comprises positioning the baffle to cover a corresponding through hole of the plurality of through holes to prevent the plurality of micro light emitting diodes from failing through the plurality of through holes.

4. The mass transfer method of claim 2, wherein Block S1-3, further comprises moving the baffle to block the opening to prevent the plurality of micro light emitting diodes from falling through the opening.

5. The mass transfer method of claim 1, wherein Block S1-1 comprises providing three transfer cavities;
Block S2-1 comprises:
placing a plurality of micro light emitting diodes, of the plurality of micro light emitting diodes, emitting light of one color in one of the three transfer cavities.

6. The mass transfer method of claim 5, wherein in Block S1-1, the three transfer cavities are provided to accommodate micro light emitting diodes emitting red light, green light, and blue light respectively.

7. The mass transfer method of claim 5, wherein in Block S1-1, the three transfer cavities are further provided such that a size of the plurality of through holes in a corresponding transfer cavity, of the three transfer cavity, is configured to accommodate the plurality of micro light emitting diodes emitting light of the one color.

8. The mass transfer method of claim 1, wherein Block S3 comprises:
Block S3-1: aligning the array substrate to the three transfer cavities sequentially, so that the plurality of capture holes are filled with the plurality of micro light emitting diodes via the three transfer cavities respectively; or
Block S3-2: aligning the array substrate to the three transfer cavities simultaneously, so that the plurality of capture holes are filled with the plurality of micro light emitting diodes via the three transfer cavities respectively.

9. The mass transfer method of claim 8, wherein in a case that Block S3 further comprises Block S3-1, Block S5 further comprises moving the array substrate along a first direction to align corresponding capture holes, of the plurality of capture holes, with the through holes of the corresponding transfer cavities accommodating the micro light emitting diodes emitting another color.

10. The mass transfer method of claim 8, wherein in a case that Block S3 further comprises Block S3-2, Block S1-1 further comprises providing the plurality of transfer cavities in one line and moving the array substrate accordingly.

11. The mass transfer method of claim 1, wherein each of the plurality of micro light emitting diodes comprises a first magnetic pole, and Block S4 comprises:
Block S4-1: providing at least one magnetic generator on a side of the array substrate away from the bottom plate to generate a magnetic field; and
Block S4-2: attracting each of the plurality of micro light emitting diodes into the corresponding the capture holes through the plurality of through holes using the magnetic field.

12. The mass transfer method of claim 11, wherein a micro light emitting diode received in one of the plurality of capture holes prevents another micro light emitting diode from falling into a same capture hole.

13. The mass transfer method of claim 11, wherein Block S4-1 comprises providing three magnetic generators corresponding to the three transfer cavities respectively, and powering on a corresponding magnetic generator of the three magnetic generators when the array substrate is aligned with a corresponding one of the three transfer cavities.

14. The mass transfer method of claim 11, wherein Block S4-2 comprises orienting each of the plurality of micro light emitting diodes such that the first magnetic pole faces toward the array substrate during falling.

15. The mass transfer method of claim 11, wherein each of the plurality of micro light-emitting diodes comprises a light emitting part and an electrode on a side of the light emitting part, and the electrode is the first magnetic pole.

16. The mass transfer method of claim 1, wherein Block S4 comprises causing each of the plurality of micro light emitting diodes fall into the corresponding one of the plurality of capture holes by gravity.

17. The mass transfer method of claim 16, wherein each of the plurality of micro light emitting diodes comprises a light-emitting part and two electrodes arranged on opposite sides of the light-emitting part, and falling by gravity causes one of the electrodes to contact a bottom of the corresponding one of the plurality of capture holes.

18. The mass transfer method of claim 1, wherein the plurality of through holes in each of the at least one transfer cavity are arranged in an array, and Block S3 comprises aligning the array of through holes with an array of the plurality of capture holes in the array substrate.

19. The mass transfer method of claim 1, wherein a number of the plurality of micro light emitting diodes in each of the at least one transfer cavity is greater than a number of the plurality capture holes in the array substrate, and the number of the plurality of capture holes is greater than a number of the plurality of through holes.

20. A mass transfer method comprising:
providing a transfer cavity comprising a bottom plate, a plurality of through holes defined in the bottom plate and a plurality of micro light emitting diodes;
providing an array substrate defining a plurality of capture holes;
attaching the array substrate to the bottom plate such that the array substrate controls release of the plurality of micro light emitting diodes through the plurality of through holes;
moving the array substrate while attached to the bottom plate to sequentially align unfilled capture holes of the plurality of capture holes with the plurality of through holes; and
allowing one of the plurality of micro light emitting diodes to fall into each unfilled capture hole of the plurality of capture holes when aligned with a corresponding one of the plurality of through holes.
